(19) United States
(12) Patent Application Publication
(10) Pub. No.: US 2008/0224309 A1
(43) Pub. Date: Sep. 18, 2008

(54) SEMICONDUCTOR DEVICE MOUNTED ON SUBSTRATE, AND MANUFACTURING METHOD THEREOF

(75) Inventor: Eiji Hori, Tokyo (JP)

Correspondence Address: DICKSTEIN SHAPIRO LLP, 1177 AVENUE OF THE AMERICAS (6TH AVENUE), NEW YORK, NY, 10036-2714, US

(73) Assignee: NEC CORPORATION, Tokyo (JP)

(21) Appl. No.: 12/032,136

(22) Filed: Feb. 15, 2008

(30) Foreign Application Priority Data
Mar. 9, 2007 (JP) 2007-059513

(51) Int. Cl. H01L 23/48

(52) U.S. Cl. 257/737

(57) ABSTRACT

The connection technology is provided in which, at the time of mounting the semiconductor device on the substrate, the thermal load or the stress, which is imposed upon the semiconductor device, is little, a reliability of the semiconductor device is obtained, a stand-off of the semiconductor device mounted on the substrate can be secured appropriately, and moreover the short circuit hardly occurs between the pads of the semiconductor device mounted on the substrate.

The semiconductor device mounted on the substrate, in which the substrate includes an electrode pad, the semiconductor device includes an electrode pad, the electrode pad of the semiconductor device and the electrode pad of the substrate are connected with a conductive adhesive, and a spacer is provided between the semiconductor device and the substrate.

### INCORPORATION BY REFERENCE

This application is based upon and claims the benefit of priority from Japanese patent application No. 2007-059513, filed on Mar. 9, 2007, the disclosure of which is incorporated herein in its entirety by reference.

### RELATED ART

The present invention relates to a semiconductor device mounted on a substrate. The present invention, more particularly, relates to a device in which an electrode pad of a semiconductor device such as an LSI and an electrode pad of a substrate are connected with a conductive adhesive.

The semiconductor device such as the LSI is packaged on the substrate (a print substrate: a package substrate) with a flip chip bonding. For example, a solder ball or a solder bump is employed for this packaging. For example, Sn—Pb lead solder has been employed as a solder material.

As it is, the lead (Pb) solder has begun to be kept at a distance due to the environmental problem. That is, the solder material that dose not contain lead (Pb) has been proposed (JP-P2006-313826A). For example, the lead-free solder material such as an Sn—Ag—Cu material has been proposed.

As it is, the lead-free solder material is high in a melting point. Thus, the soldering necessitates a work at a high temperature. However, the soldering practice at a high temperature imposes a large thermal load upon a substrate or an installed part. Further, the lead-free solder material is high in an elasticity coefficient. Thus, the stress is prone to be applied to a neighborhood of the soldering region. As it is, a so-called porous film such as a Low-k film in the LSI has a structure susceptible to the stress. Thus, when the stress is applied, the film is prone to be exfoliated. For this reason, a reliability of the LSI declines.

By the way, the bonding technology employing no solder is known. That is, the technology employing the adhesive that is comprised of conductive resin has been proposed (JP-P2005-311209A).

This conductive resin adhesive can be used at a lower temperature as compared with the solder material. Thus, the thermal load imposed upon the substrate or the installed part is very small. Further, the stress as well is small, and the possibility as well that the LSI is damaged is low.

By the way, the connection technology employing the conductive resin adhesive is called a stud bump method. The cross-section of the connection in which the LSI chip has been mounted on the substrate by employing this stud bump method is shown in FIG. 6. At first, prior to the bonding, a stud 21b is formed on an Al electrode 21a of an LSI chip 21 by employing a gold fine wire etc. And, after a pad 23 formed on a substrate 22 is coated with a conductive resin adhesive 24, the LSI chip 21 is mounted on the substrate 22. Thereafter, a heat treatment is performed and the conductive resin adhesive 24 is hardened.

[Patent document 1] JP-P2006-313826A

[Patent document 2] JP-P2005-311209A

By the way, it has become clear that the stud bump method as well employing the conductive resin adhesive has a problem. That is, the stud bump method necessitates pre-forming the Au stud 21b on the Al electrode 21a. For this reason, it becomes costly.

### SUMMARY OF THE INVENTION

Thus, a first problem to be solved by the present invention is to provide a connection technology that does not employ Pb at the time of mounting the semiconductor device on the substrate.

A second problem to be solved by the present invention is to provide a technology capable of making a connection at a low temperature at the time of mounting the semiconductor device on the substrate.

A third problem to be solved by the present invention is to provide a technology that does not necessitates forming the Au stud at the time of mounting the semiconductor device on the substrate.

A fourth problem to be solved by the present invention is to provide a connection technology in which the thermal load or the stress imposed upon the semiconductor device is little and a reliability of the device is obtained at the time of mounting the semiconductor device on the substrate.

A fifth problem to be solved by the present invention is to provide a connection technology of which the cost is inexpensive at the time of mounting the semiconductor device on the substrate.

A sixth problem to be solved by the present invention is to provide a connection technology that enables a standoff of the semiconductor device mounted on the substrate to be secured appropriately.

A seventh problem to be solved by the present invention is to provide a connection technology in which a short circuit hardly occurs between the pads of the semiconductor device mounted on the substrate.

The present inventor aggressively has made an investigation for solving the above-mentioned problems.

At first, the inventor promoted a development for realizing the bonding at a low temperature and yet at a low cost.

Thereupon, the connection only by the conductive resin adhesive (simply, also referred to as a conductive adhesive) occurred to the inventor. As it is, upon carrying out this technical conception, an incline of the mounted LSI chip was confirmed. Further, the semiconductor device as well having the possibility that a short circuit occurred between the pads was confirmed. That is, even though the conductive adhesive melts similarly to the solder (metal material), it is not spheroidized. And, it was impossible to expect a self-alignment effect, differently from the case of the solder. Yet, the LSI chip precipitates due to its dead weight at the time of mounting the LSI, or at the moment of hardening the conductive adhesive because the member (member such as the stud bump) that regulates a gap (a height of the connection: a standoff) between the LSI chip and the substrate does not exist. Thereby, the standoff of the LSI becomes smaller than the setting value. Further, the possibility that the adhesive oozed out to the surrounding, and the short circuit occurred between the neighboring pads became high.

As a result of further having continued the investigation based upon such knowledge, the inventor has attained the present invention.

That is, the above-mentioned problem is solved by a semiconductor device mounted on a substrate: wherein the substrate includes an electrode pad; wherein the semiconductor device includes an electrode pad; wherein the electrode pad of the semiconductor device and the electrode pad of the substrate are connected with a conductive adhesive: and wherein a spacer is provided between the semiconductor device and the substrate.

Further, the above-mentioned problem is solved by a method of manufacturing a semiconductor device mounted on a substrate that includes: a coating step of coating a position of an electrode pad and spacer arrangement position of the substrate with a conductive adhesive; a spacer arrangement step of arranging the spacer at the spacer arrangement position; a mounting step of, after the coating step and the spacer arrangement step, mounting the semiconductor device on the substrate by causing the electrode pad of the semiconductor device to correspond to the electrode pad of the substrate; and a hardening step of, after the mounting step, hardening the conductive adhesive.

Further, the above-mentioned problem is solved by a method of manufacturing a semiconductor device mounted on a substrate that includes: a coating step of coating a position of an electrode pad of the substrate with a conductive adhesive; a spacer arrangement step of arranging a spacer at a desirable position of the substrate; a mounting step of, after the coating step and the spacer arrangement step, mounting the semiconductor device on the substrate by causing the electrode pad of the semiconductor device to correspond to the electrode pad of the substrate; and a hardening step of, after the mounting step, hardening the conductive adhesive.

Further, the above-mentioned problem is solved by a method of manufacturing a semiconductor device mounted on a substrate that includes: a coating step of coating a position of an electrode pad of the substrate with a conductive adhesive; a spacer arrangement step of arranging a spacer at a desirable position of the semiconductor device; a mounting step of, after the coating step and the spacer arrangement step, mounting the semiconductor device on the substrate by causing the electrode pad of the semiconductor device to correspond to the electrode pad of the substrate; and a hardening step of, after the mounting step, hardening the conductive adhesive.

The conductive adhesive is hardenable at a temperature of approx. 200° C. or less. Moreover, the elasticity coefficient of the hardened conductive adhesive is far smaller than that of the lead-free solder. Thus, employment of the conductive adhesive hardly imposes the thermal load or the stress upon the semiconductor device at the moment of mounting the semiconductor device on the substrate. Thus, a reliability f the semiconductor device hardly declines.

Further, mounting the spacer between the semiconductor device and the substrate prevents the semiconductor device from precipitating even though the conductive adhesive is softened at the moment of the connection. That is, the standoff of the semiconductor device can be sufficiently secured. And, there is no possibility that the conductive adhesive is pressed and spread due to a precipitation pressure because no precipitation of the semiconductor device occurs. Thus, the short circuit hardly occurs between the neighboring pads.

Further, formation of the Au stud is not necessitated. Thus, the cost is inexpensive because the step such as the step of forming the Au stud that is costly does not exist.

### BRIEF DESCRIPTION OF THE DRAWING

This and other objects, features and advantages of the present invention will become more apparent upon a reading of the following detailed description and a drawing, in which:

FIG. 1a, 1b is a cross-sectional view of a semiconductor device of a first embodiment of the present invention;

FIG. 2a, 2b, 2c, 2d is a view of the step of manufacturing the semiconductor device of the first embodiment of the present invention;

FIG. 3 is a cross-sectional view of a semiconductor device of a second embodiment of the present invention;

FIG. 4a, 4b, 4c is a view of the step of manufacturing a semiconductor device of a third embodiment of the present invention;

FIG. 5a,5b,5c is a view of the step of manufacturing a semiconductor device of a fourth embodiment of the present invention; and

FIG. 6 is a cross-sectional view of the conventional semiconductor device.

### EXEMPLARY OF THE EMBODIMENTS

The present invention relates to a semiconductor device mounted on a substrate. The substrate has an electrode pad. The semiconductor device has an electrode pad. And, the electrode pad of the semiconductor device and the electrode pad of the substrate are connected with the conductive adhesive (conductive resin adhesive). Yet, a spacer is provided between the semiconductor device and the substrate. The number of the spacer is desirably plural. In particular, three or more are more desirably provided. That is, providing three spacers or more between the semiconductor device and the substrate makes it possible to keep the semiconductor device at a horizontal level. The spacer is desirably provided corresponding to a corner part of the semiconductor device. That is, providing the spacer in the corner part prevents the spacer from disturbing the other part. Further, the spacer is desirably mounted on a dummy pad of the substrate. Further, the spacer is desirably fixed to the semiconductor device and/or the substrate with the adhesive. That is, by fixing the spacer to the semiconductor device or the substrate, the mounting practice of the semiconductor device is smoothly performed. Further, no hindrance occurs even after mounting because the spacer does not move. Additionally, this adhesive could be not only a non-conductive resin adhesive but also a conductive adhesive. Further, the spacer is desirably embedded into the conductive adhesive. Doing so eliminates a necessity of purposely coating the spacer with the adhesive. Additionally, the semiconductor device is, for example, an LSI, which is a bear chip or a packaged chip.

Further, the present invention relates to a method of manufacturing a semiconductor device mounted on a substrate. In particular, the present invention relates to a method of manufacturing a semiconductor device mounted on the above-mentioned substrate. And, the method includes a coating step of coating a position of an electrode pad and spacer arrangement position of the substrate with a conductive adhesive. Further, the method includes a spacer arrangement step of arranging the spacer at the spacer arrangement position. The method includes a mounting step of, after the coating step and the spacer arrangement step, mounting the semiconductor device on the substrate by causing the electrode pad of the semiconductor device to correspond to the electrode pad of the substrate. Further, the method includes a hardening step of, after the mounting step, hardening the conductive adhesive.

Or, the method includes a coating step of coating a position of an electrode pad of the substrate with a conductive adhesive. Further, the method includes a spacer arrangement step of arranging a spacer at a desirable position of the substrate. Further, the method includes a mounting step of, after the coating step and the spacer arrangement step, mounting the semiconductor device on the substrate by causing the electrode pad of the semiconductor device to correspond to the electrode pad of the substrate. Further, the method includes a hardening step of, after the mounting step, hardening the conductive adhesive.

Further, the method includes a coating step of coating a position of an electrode pad of the substrate with a conductive adhesive. Further, the method includes a spacer arrangement step of arranging a spacer at a desirable position of the semiconductor device. Further, the method includes a mounting step of, after the coating step and the spacer arrangement step, mounting the semiconductor device on the substrate by causing the electrode pad of the semiconductor device to correspond to the electrode pad of the substrate. Further, the method includes a hardening step of, after the mounting step, hardening the conductive adhesive.

Hereinafter, the embodiments will be further explained specifically.

### First Embodiment

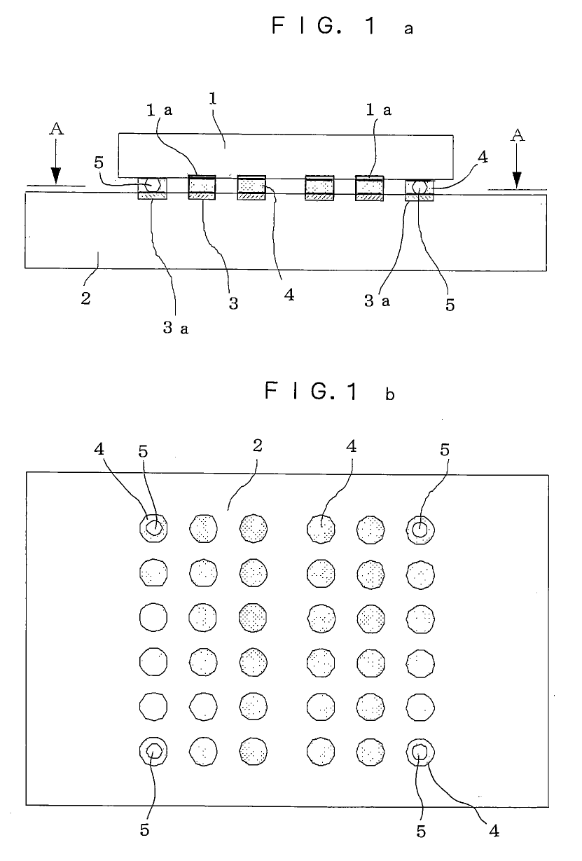

FIG. 1 shows the first embodiment of the present invention, FIG. 1a is a cross-sectional view, and FIG. 1b is a cross-sectional view in the substrate side taken across an A-A line of FIG. 1a.

In FIG. 1a,1b, 1 is an LSI chip (semiconductor device). 1a is an electrode pad provided in the LSI chip 1.

2 is a substrate. Additionally, the parts such as a semiconductor chip such as other LSI, a resister, and a condenser may be mounted on the substrate 2. Further, the substrate 2 could be a rigid or a flexible resin substrate. Further, the substrate 2 could be a ceramic substrate. A wiring may be formed on one side or both sides of the substrate. Moreover, the wiring could be a multi-layer wiring. Further, the substrate 2 could be a BGA carrier substrate or a CSP carrier substrate.

3 is an electrode pad provided in the substrate 2. Additionally, the position of an electrode pad 1a and that of the electrode pad 3 correspond to each other. That is, in a case of mounting the LSI chip 1 on the substrate 2, the position of the electrode pad 1a coincides with that of the electrode pad 3.

Additionally, a conductor (wiring) is coupled to the electrode pads 1a and 3, which is not shown in the figure.

3a is a dummy pad provided in the substrate 2. This dummy pad 3a, in particular, is provided in a position that corresponds to four corners (corner part) of the LSI chip 1. However, the dummy pad 3a is not coupled to the conductor (wiring).

4 is a conductive adhesive. This conductive adhesive 4 is an adhesive with which, for example, the pad 3 and the dummy pad 3a have been coated. And, the electrode pad 1a of the LSI chip 1 and the pad 3 of the substrate 2 are electronically connected with the conductive adhesive 4.

5 is a spacer (in particular, a spherical (ball-shape) spacer). This spacer 5 assumes an aspect of being embedded into the conductive adhesive 4 with which the dummy pad 3a has been coated. And, the spacer 5 allows a distance between the LSI chip 1 and the substrate 2 to be kept at a constant. That is, the spacer 5 enables a height (standoff) of the LSI chip 1 to be maintained at a desirable value. Additionally, the spacer, of which the shape is of a globe having a constant diameter, could be any of a spacer made of resin and a spacer made of metal. Further, desirably, the shape of the spacer is globular; however it is not limited to the glove.

The conductive adhesive 4 is an adhesive obtained by blending conductive filler such as metal powder with resin (in particular, thermoplastic resin). As a resin material, for example, epoxy resin, polyester resin, acrylic resin melamine resin, polyimide resin, phenol resin, silicon resin, and so on are employed. Needless to say, the conductive adhesive 4 could be an adhesive made of one kind, and could be an adhesive obtained by blending two kinds or more. The conductive grain that is added to the resin material is a metal (for example, Ag, Cu, Cu alloy, Au, Pd, Ag—Pb alloy, Ni, or the like) grain, a carbon, or the like. Further, nanopaste into which nano-sized metal powder has been blended can be used. In this case, the connection having a low resistance is enabled owing to a cure at a low temperature. The commercially available adhesive as well can be appropriately employed as a conductive adhesive.

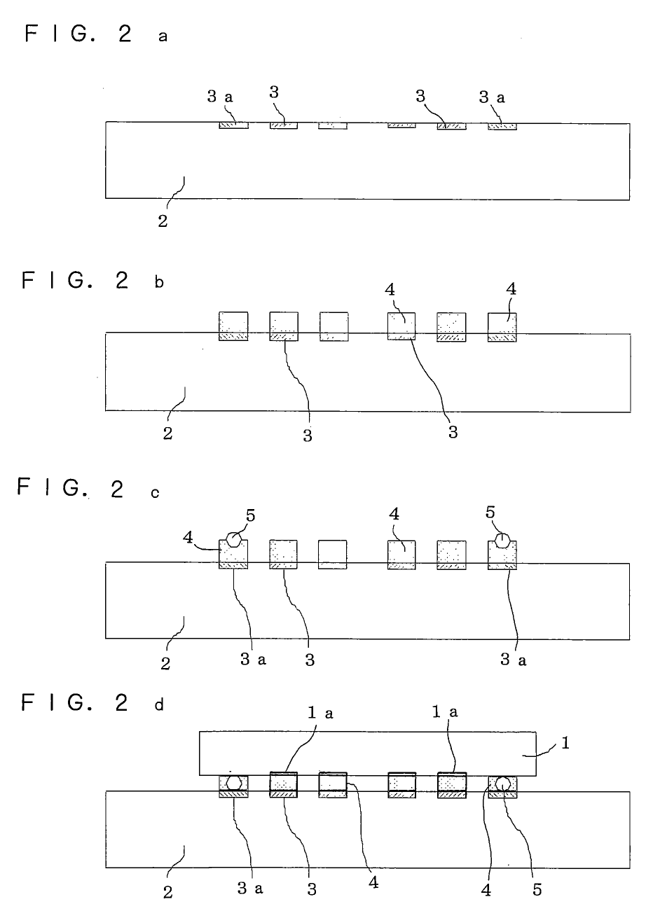

Next, the method of manufacturing the device shown in FIG. 1a,1b will be explained by making a reference to FIG. 2a˜2d.

At first, the substrate 2 in which the pad 3 has been provided at a position that corresponds to the position of the electrode pad 1a of the LSI chip 1, or the substrate 2 in which the dummy pad 3a has been provided at a position that corresponds to the four corners of the LSI chip 1 is prepared (see FIG. 2a).

Next, the pad 3 and the dummy pad 3a of the substrate 2 are coated with the conductive adhesive 4 by means of a screen print method or the like (see FIG. 2b). Additionally, a microdispenser or a jet printer may be employed to coat them with the conductive adhesive 4.

And, the spacer 5 is arranged on the conductive adhesive 4 on the dummy pad 3a (see FIG. 2c).

Thereafter, the LSI chip 1 is mounted on the substrate 2 so that the electrode pad 3 of the substrate 2 coincides with the electrode pad 1a of the LSI chip 1 (see FIG. 2d).

And, the heat treatment is performed, thereby to harden the conductive adhesive 4. With this, the device shown in FIG. 1a,1b is obtained.

Additionally, in a case where the conductive adhesive is an ultra-violent ray (electron beam) hardenable type adhesive, the conductive adhesive is irradiated with the ultra-violent ray (electron beam) instead of the heat treatment.

### Second Embodiment

FIG. 3 is a cross-sectional view illustrating the second embodiment of the present invention.

In FIG. 3, and FIG. 1a, the identical numerical code is affixed to the identical part, and the detailed explanation is omitted.

In this embodiment, the substrate 2 does not have the dummy pad 3a. Further, the spacer 5 arranged in the location that corresponds to the four corners of the LSI chip 1 is a spacer bonded with a non-conductive adhesive 6.

In the first embodiment, the arrangement position of the spacer 5 was pre-coated with the conductive adhesive. However, in this method, the quantity of the conductive adhesive with which the above location is coated is prone to be excessive. Doing so incurs the possibility that the short circuit occurs between the pads via the conductive adhesive on the dummy pad.

Thereupon, in this embodiment, the coating step with the adhesive 6 was provided apart from the coating step with the conductive adhesive 4. And, the arrangement position of the spacer 5 was coated with the adhesive of which the quantity is appropriate.

### Third Embodiment

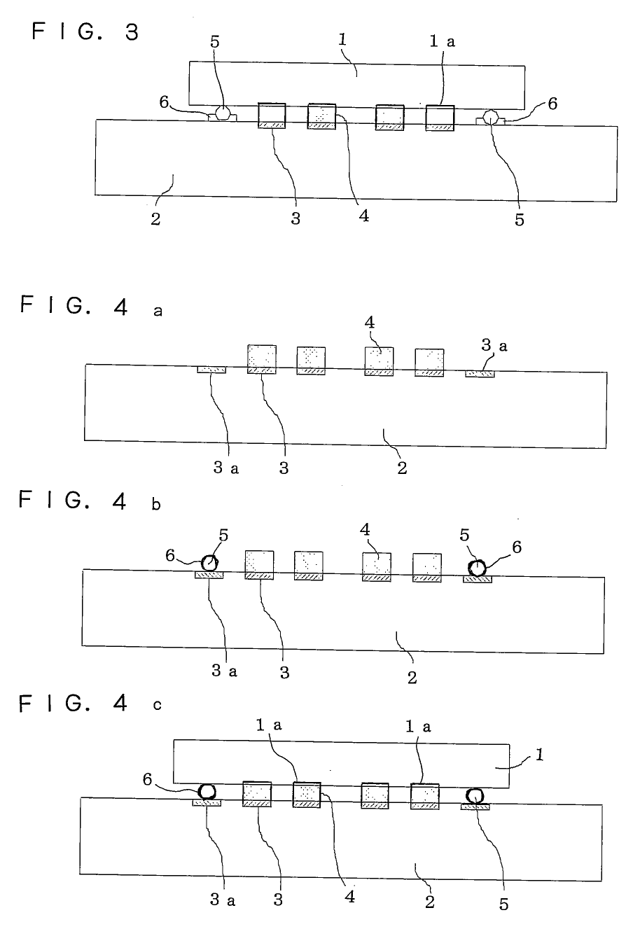

FIG. 4a,4b,4c is a view (cross-sectional view) of the step of manufacturing the device of the third embodiment of the present invention.

At first, the pad 3 of the substrate 2 similar to that of the case of the first embodiment is coated with the conductive adhesive 4 by means of the screen print method or the like (see FIG. 4a). Additionally, the dummy pad 3a is not coated with the conductive adhesive 4.

Next, the spacer 5 of which the surface has been uniformly coated with the adhesive 6 is arranged on the dummy pad 3a (see FIG. 4b).

Thereafter, the LSI chip 1 is mounted on the substrate 2 so that the electrode pad 3 of the substrate 2 coincides with the electrode pad 1a of the LSI chip 1 (see FIG. 4c).

And, the heat treatment is performed, thereby to harden the conductive adhesive 4. With this, the device of the present invention is obtained.

### Fourth Embodiment

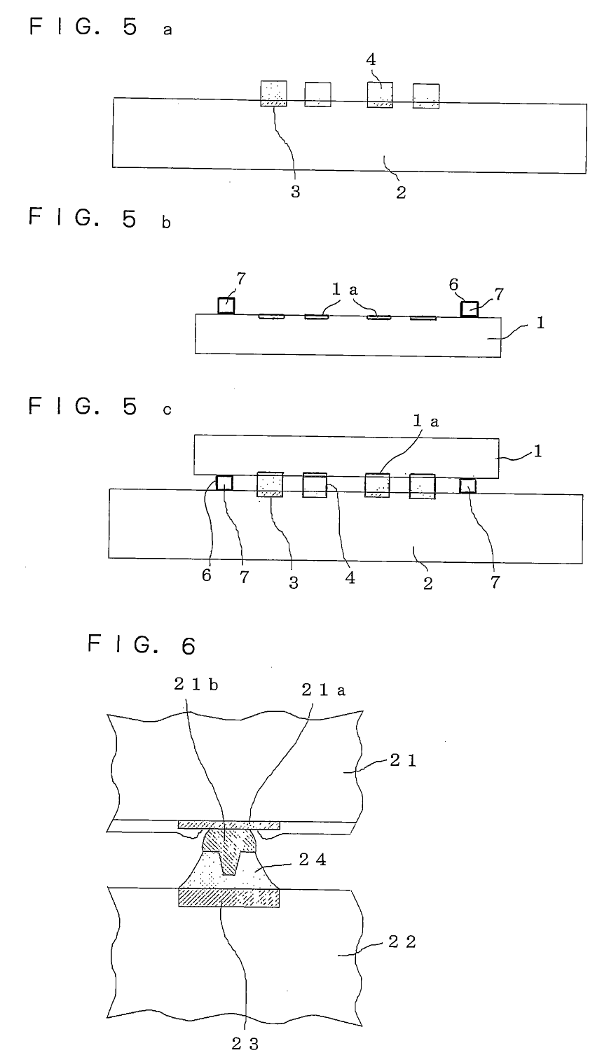

FIG. 5a,5b,5c is a view (cross-sectional view) of the step of manufacturing the device of the fourth embodiment of the present invention.

At first, the pad 3 of the substrate 2 similar to that of the case of the second embodiment is coated with the conductive adhesive 4 by means of the screen print method or the like (see FIG. 5a).

Next, a cube-shaped spacer 7 of which the surface has been pre-coated with the adhesive 6 is arranged in the four corners of the surface on which the electrode pad 1a of the LSI chip 1 has been formed (see FIG. 5b).

Thereafter, the LSI chip 1 is mounted on the substrate 2 so that the electrode pad 3 of the substrate 2 coincides with the electrode pad 1a of the LSI chip 1 (see FIG. 5c).

And, the heat treatment is performed, thereby to harden the conductive adhesive 4.

Additionally, any step of the step of FIG. 5a and the step of FIG. 5b may be performed ahead of the other, and further both steps may be performed simultaneously. Further, the adhesive 6 may be hardened or pre-baked in the step shown in FIG. 5b.

While the present invention has been particularly shown and described with the reference to exemplary embodiments thereof, the present invention is not limited to these embodiments. That is, various changes in form and details may be made therein without departing from the spirit and scope of the present invention as defined by the claims. For example, in the above-mentioned embodiments, the mounted part is an LSI chip; however it could be a packaged chip such as a CSP chip. Further, the glove-shaped spacer and the cube-shaped spacer were explained as a spacer; however the appropriately-shaped spacers such as a columnar spacer, a tetrahedron-shape spacer, and so on can be employed in addition hereto. Further, the arrangement position of the spacer is not limited to the four corners of the LSI, and the appropriate region in which the electrode pad of the LSI has not been formed may be selected for arrangement.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A semiconductor device mounted on a substrate:
wherein said substrate comprises an electrode pad;
wherein said semiconductor device comprises an electrode pad;
wherein the electrode pad of said semiconductor device and the electrode pad of said substrate are connected with a conductive adhesive; and
wherein a spacer is provided between said semiconductor device and said substrate.

2. The semiconductor device mounted on a substrate as claimed in claim 1, wherein the number of said provided spacer is plural.

3. The semiconductor device mounted on a substrate as claimed in claim 1, wherein said spacer is provided corresponding to a corner part of said semiconductor device.

4. The semiconductor device mounted on a substrate as claimed in claim 1, wherein said spacer is provided on a dummy pad of said substrate.

5. The semiconductor device mounted on a substrate as claimed in claim 1, wherein said spacer is fixed to said semiconductor device and/or said substrate with an adhesive.

6. The semiconductor device mounted on a substrate as claimed in claim 5, wherein the adhesive is a conductive adhesive.

7. The semiconductor device mounted on a substrate as claimed in claim 1, wherein said spacer is embedded into said conductive adhesive.

8. The semiconductor device mounted on a substrate as claimed in claim 1:
wherein said semiconductor device is an LSI; and
wherein said LSI is one of a bear chip and a packaged chip.

9. A method of manufacturing a semiconductor device mounted on a substrate, said method comprising:
a coating step of coating a position of an electrode pad and spacer arrangement position of said substrate with a conductive adhesive;
a spacer arrangement step of arranging the spacer at said spacer arrangement position;
a mounting step of, after said coating step and said spacer arrangement step, mounting said semiconductor device on said substrate by causing the electrode pad of said semiconductor device to correspond to the electrode pad of said substrate; and
a hardening step of, after said mounting step, hardening said conductive adhesive.

10. A method of manufacturing a semiconductor device mounted on a substrate, said method comprising:
a coating step of coating a position of an electrode pad of said substrate with a conductive adhesive;
a spacer arrangement step of arranging a spacer at a desirable position of said substrate;
a mounting step of, after said coating step and said spacer arrangement step, mounting said semiconductor device on said substrate by causing the electrode pad of said semiconductor device to correspond to the electrode pad of said substrate; and
a hardening step of, after said mounting step, hardening said conductive adhesive.

11. The method of manufacturing a semiconductor device mounted on a substrate as claimed in claim 10, said method comprising a coating step of pre-coating said spacer with the adhesive.

12. A method of manufacturing a semiconductor device mounted on a substrate, said method comprising:
a coating step of coating a position of an electrode pad of said substrate with a conductive adhesive;
a spacer arrangement step of arranging a spacer at a desirable position of said semiconductor device;
a mounting step of, after said coating step and said spacer arrangement step, mounting said semiconductor device on said substrate by causing the electrode pad of said semiconductor device to correspond to the electrode pad of said substrate; and
a hardening step of, after said mounting step, hardening said conductive adhesive.

13. The method of manufacturing a semiconductor device mounted on a substrate as claimed in claim 12, said method comprising a coating step of pre-coating said spacer with the adhesive.
